(19) United States
(12) Patent Application Publication
(10) Pub. No.: US 2026/0015731 A1
(43) Pub. Date: Jan. 15, 2026

(54) PROCESSING METHOD, METHOD OF MANUFACTURING SEMICONDUCTOR DEVICE, PROCESSING APPARATUS, AND RECORDING MEDIUM

(71) Applicant: KOKUSAI ELECTRIC CORPORATION, Tokyo (JP)

(72) Inventor: Kimihiko NAKATANI, Toyama-shi (JP)

(73) Assignee: KOKUSAI ELECTRIC CORPORATION, Tokyo (JP)

(21) Appl. No.: 19/332,505

(22) Filed: Sep. 18, 2025

Related U.S. Application Data
(63) Continuation of application No. PCT/JP2023/021234, filed on Jun. 7, 2023.

(51) Int. Cl. C23C 16/56; C23C 16/455; C23C 16/52; H01L 21/02

(52) U.S. Cl. CPC C23C 16/56; C23C 16/45544; C23C 16/45553; C23C 16/52; H01L 21/02337

(57) ABSTRACT

There is provided a technique that includes: (a) forming a first film, containing at least a portion of a partial structure X and a partial structure Z derived from a partial structure Y, on a substrate by supplying, to the substrate, a precursor containing both the partial structure X and the partial structure Y, or a first precursor containing the partial structure X and a second precursor containing the partial structure Y; and (b) modifying the first film formed on the substrate into a second film by exposing the first film to a modifying agent, the second film containing at least a portion of the partial structure X and a smaller amount of the partial structure Z than that contained in the first film.

### CROSS-REFERENCE TO RELATED APPLICATION

This application is a Bypass Continuation Application of PCT International Application No. PCT/JP2023/021234, filed on Jun. 7, 2023, the disclosure of which is incorporated herein in its entirety by reference.

### TECHNICAL FIELD

The present disclosure relates to a processing method, a method of manufacturing a semiconductor device, a processing apparatus, and a recording medium.

### BACKGROUND

As a process of manufacturing semiconductor devices, forming a film on a substrate may be performed.

### SUMMARY

Some embodiments of the present disclosure provide a technique capable of improving a processing resistance of a film formed on a substrate and achieving a lower dielectric constant.

According to some embodiments of the present disclosure, there is provided a technique that includes: (a) forming a first film, containing at least a portion of a partial structure X and a partial structure Z derived from a partial structure Y, on a substrate by supplying, to the substrate, a precursor containing both the partial structure X and the partial structure Y, or a first precursor containing the partial structure X and a second precursor containing the partial structure Y; and (b) modifying the first film formed on the substrate into a second film by exposing the first film to a modifying agent, the second film containing at least a portion of the partial structure X and a smaller amount of the partial structure Z than that contained in the first film.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic configuration diagram of a vertical process furnace of a processing apparatus suitably used in one embodiment of the present disclosure, illustrating a portion of a process furnace in a vertical cross-sectional view.

FIG. 2 is a schematic configuration diagram of the vertical process furnace of the processing apparatus suitably used in one embodiment of the present disclosure, illustrating a portion of the process furnace in a cross-sectional view taken along line A-A of FIG. 1.

FIG. 3 is a schematic configuration diagram of a controller of the processing apparatus suitably used in one embodiment of the present disclosure, illustrating a control system of the controller in a block diagram.

FIG. 4 is a diagram illustrating a processing sequence according to a first embodiment of the present disclosure.

FIG. 5 is a diagram illustrating a processing sequence according to a second embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to unnecessarily obscure aspects of the various embodiments.

### First Embodiment of Present Disclosure

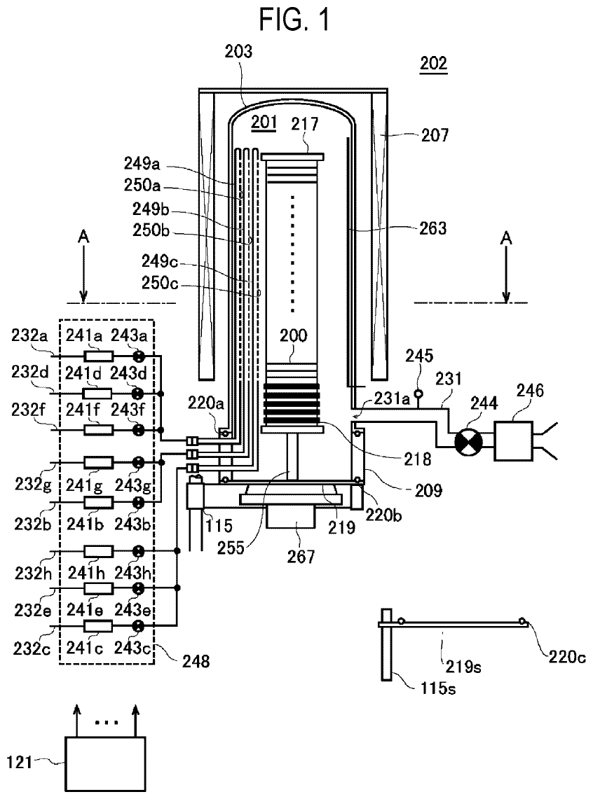

Hereinafter, a first embodiment of the present disclosure will be described mainly with reference to FIGS. 1 to 4. In addition, drawings used in the following description are schematic, and dimensional relationships, ratios, and the like of various elements shown in the drawings may not match actual ones. Further, the dimensional relationships, ratios, and the like of various elements among plural drawings may not match one another.

### (1) Configuration of Processing Apparatus

As illustrated in FIG. 1, a process furnace 202 of a processing apparatus includes a heater 207 serving as a temperature regulator (heating part). The heater 207 is formed in a cylindrical shape and is supported by a support plate so as to be vertically installed. The heater 207 also functions as an activator (a thermal exciter) configured to thermally activate (excite) a gas.

A reaction tube 203 is disposed to be concentric with the heater 207 inside the heater 207. The reaction tube 203 is made of, for example, a heat resistant material such as quartz (SiO₂) or silicon carbide (SiC), and is formed in a cylindrical shape with its upper end closed and its lower end open. A manifold 209 is disposed to be concentric with the reaction tube 203 under the reaction tube 203. The manifold 209 is made of, for example, a metal material such as stainless steel (SUS), and is formed in a cylindrical shape with its upper and lower ends open. The upper end of the manifold 209 is engages with the lower end of the reaction tube 203 so as to support the reaction tube 203. An O-ring 220a is installed as a seal between the manifold 209 and the reaction tube 203. The reaction tube 203 is installed vertically in the same manner as the heater 207. A process container (reaction container) mainly includes the reaction tube 203 and the manifold 209. A process chamber 201 is formed in a hollow cylindrical region of the process container. The process chamber 201 is configured to be capable of accommodating wafers 200 serving as substrates. The wafers 200 are processed inside the process chamber 201.

Nozzles 249a to 249c are installed as first to third suppliers inside the process chamber 201 so as to penetrate a sidewall of the manifold 209, respectively. The nozzles 249a to 249c are also referred to as first to third nozzles, respectively. The nozzles 249a to 249c are made of, for example, a heat resistant material such as quartz or SiC. Gas supply pipes 232a to 232c are connected to the nozzles 249a to 249c, respectively. The nozzles 249a to 249c are different nozzles, respectively, and each of the nozzles 249a and 249c is installed adjacent to the nozzle 249b.

The gas supply pipes 232a to 232c are installed, respectively, with mass flow controllers (MFCs) 241a to 241c, which serve as flow rate controllers (flow rate control parts), and valves 243a to 243c, which serve as opening/closing valves, sequentially from the upstream side of a gas flow. Gas supply pipes 232d and 232f are connected to the gas supply pipe 232a at the downstream side of the valve 243a. A gas supply pipe 232g is connected to the gas supply pipe 232b at the downstream side of the valve 243b. Gas supply pipes 232e and 232h are connected to the gas supply pipe 232c at the downstream side of the valve 243c. The gas supply pipes 232d to 232h are installed respectively with MFCs 241d to 241h and valves 243d to 243h sequentially from the upstream side of a gas flow. The gas supply pipes 232a to 232h are made of, for example, a metal material such as SUS.

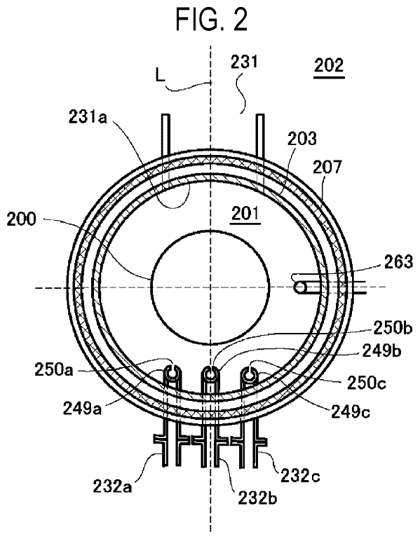

As illustrated in FIG. 2, the nozzles 249a to 249c are installed at an annular space in a plane view between an inner wall of the reaction tube 203 and the wafers 200, so as to extend upward from a lower side to an upper side of the inner wall of the reaction tube 203, along the direction in which the wafers 200 are arranged. In other words, the nozzles 249a to 249c are installed in a region horizontally surrounding a wafer arrangement region, in which the wafers 200 are arranged, at a lateral side of the wafer arrangement region, so as to be aligned along the wafer arrangement region. The nozzle 249b is positioned to linearly oppose an exhaust port 231a, which will be described later, across the center of the wafers 200 inside the process chamber 201 in a plane view. The nozzles 249a and 249c are positioned to sandwich therebetween a straight line L, which passes through the centers of the nozzle 249b and the exhaust port 231a, along the inner wall of the reaction tube 203 (an outer periphery of the wafers 200). The straight line L is also a straight line passing through the centers of the nozzle 249b and wafers 200. That is, it can also be said that the nozzle 249c is installed at the opposite side of the nozzle 249a with the straight line L interposed therebetween. The nozzles 249a and 249c are positioned linearly symmetrically with the straight line L as a symmetrical axis. Gas supply holes 250a to 250c configured to supply gases are installed at side surfaces of the nozzles 249a to 249c, respectively. The gas supply holes 250a to 250c are each opened to oppose (face) the exhaust port 231a in a plane view, which enables the supply of gases toward the wafers 200. A plurality of gas supply holes 250a to 250c are installed from the lower side to the upper side of the reaction tube 203.

A precursor containing a partial structure X and a partial structure Y is supplied from the gas supply pipe 232a into the process chamber 201 via the MFC 241a, valve 243a, and nozzle 249a.

A second precursor containing the partial structure Y is supplied from the gas supply pipe 232b into the process chamber 201 via the MFC 241b, valve 243b, and nozzle 249b.

A reactant is supplied from the gas supply pipe 232c into the process chamber 201 via the MFC 241c, valve 243c, and nozzle 249c.

A first precursor containing the partial structure X is supplied from the gas supply pipe 232d into the process chamber 201 via the MFC 241d, valve 243d, gas supply pipe 232a, and nozzle 249a.

A modifying agent is supplied from the gas supply pipe 232e into the process chamber 201 via the MFC 241e, valve 243e, gas supply pipe 232c, and nozzle 249c.

An inert gas is supplied from the gas supply pipes 232f to 232h into the process chamber 201 via the MFCs 241f to 241h, valves 243f to 243h, gas supply pipes 232a to 232c, and nozzles 249a to 249c. The inert gas acts, for example, as a purge gas, a carrier gas, or a dilution gas, or the like.

A precursor supply system mainly includes the gas supply pipe 232a, MFC 241a, and valve 243a. A first precursor supply system mainly includes the gas supply pipe 232d, MFC 241d, and valve 243d. A second precursor supply system mainly includes the gas supply pipe 232b, MFC 241b, and valve 243b. The term ““precursor supply system”” may refer to each of the precursor supply system, the first precursor supply system, and the second precursor supply system, or to the entirety of them generally. A reactant supply system mainly includes the gas supply pipe 232c, MFC 241c, and valve 243c. A modifying agent exposure system (modifying agent supply system) mainly includes the gas supply pipe 232e, MFC 241e, and valve 243e. An inert gas supply system mainly includes the gas supply pipes 232f to 232h, MFCs 241f to 241h, and valves 243f to 243h.

Any or the entirety of the various supply systems described above may be configured as an integrated supply system 248 in which the valves 243a to 243h, MFCs 241a to 241h, and the like are integrated. The integrated supply system 248 is connected to each of the gas supply pipes 232a to 232h, and is configured such that supply operations of various substances (various gases) into the gas supply pipes 232a to 232h, such as opening/closing operations of the valves 243a to 243h and flow rate regulating operations by the MFCs 241a to 241h, are controlled by a controller 121, which will be described later. The integrated supply system 248 is configured as an integral or divided integrated unit, allowing attaching and detaching of the gas supply pipes 232a to 232h or the like at the integrated unit level. This enables maintenance, replacement, expansion, and the like of the integrated supply system 248 at the integrated unit level.

The exhaust port 231a configured to exhaust an internal atmosphere of the process chamber 201, is installed below a sidewall of the reaction tube 203. As illustrated in FIG. 2, the exhaust port 231a is positioned to oppose (face) the nozzles 249a to 249c (gas supply holes 250a to 250c) across the wafers 200 in a plane view. The exhaust port 231a may be installed along the sidewall of the reaction tube 203 from a lower side to an upper side, that is, along the wafer arrangement region. An exhaust pipe 231 is connected to the exhaust port 231a. The exhaust pipe 231 is connected to a vacuum pump 246, which serves as a vacuum-exhauster, via a pressure sensor 245, which serves as a pressure detector configured to detect an internal pressure of the process chamber 201, and an auto pressure controller (APC) valve 244, which serves as a pressure regulator (pressure regulating part). The APC valve 244 is configured to perform or stop a vacuum-exhaust operation in the process chamber 201 by being opened or closed while the vacuum pump 246 is actuated. The APC valve 244 is also configured to regulate the internal pressure of the process chamber 201 by adjusting a degree of valve opening based on pressure information detected by the pressure sensor 245 while the vacuum pump 246 is actuated. An exhaust system mainly includes the exhaust pipe 231, APC valve 244, and pressure sensor 245. The vacuum pump 246 may also be included in the exhaust system.

A seal cap 219, which serves as a furnace opening lid configured to be capable of hermetically sealing a lower end opening of the manifold 209, is installed under the manifold 209. The seal cap 219 is made of, for example, a metal material such as SUS, and formed in a disc shape. An O-ring 220b, which serves as a seal that makes contact against the lower end of the manifold 209, is installed on an upper surface of the seal cap 219. A rotator 267 is installed below the seal cap 219 to rotate a boat 217, which will be described later. A rotary shaft 255 of the rotator 267 is connected to the boat 217 through the seal cap 219. The rotator 267 is configured to rotate the wafers 200 by rotating the boat 217. The seal cap 219 is configured to be vertically raised or lowered by a boat elevator 115, which serves as an elevator provided outside the reaction tube 203. The boat elevator 115 is configured as a transporter (transport equipment) which loads and unloads (transports) the wafers 200 into and out of the process chamber 201 by raising or lowering the seal cap 219.

A shutter 219s which serves as a furnace opening lid capable of hermetically sealing the lower end opening of the manifold 209 in a state in which the seal cap 219 is lowered and the boat 217 is unloaded from the process chamber 201, is installed under the manifold 209. The shutter 219s is made of, for example, a metal material such as SUS and is formed in a disc shape. An O-ring 220c, which serves as a seal configured to make contact against the lower end of the manifold 209, is installed on an upper surface of the shutter 219s. The opening/closing operation (operation of moving up or down or rotating operation) of the shutter 219s is controlled by a shutter opening/closing mechanism 115s.

The boat 217, which serves as a substrate support, is configured to support a plurality of wafers 200, for example, 25 to 200 wafers, in such a state that the wafers 200 are arranged to be spaced apart from each other in a horizontal posture and in multiple stages along a vertical direction with the centers of the wafers 200 aligned with one another. The boat 217 is made of, for example, a heat resistant material such as quartz or SiC. Heat insulating plates 218 made of a heat resistant material such as quartz or SiC are installed below the boat 217 in multiple stages.

A temperature sensor 263 which serves as a temperature detector is provided inside the reaction tube 203. Based on temperature information detected by the temperature sensor 263, a state of supplying electric power to the heater 207 is regulated such that the internal temperature of the process chamber 201 falls within a desired temperature distribution. The temperature sensor 263 is installed along the inner wall of the reaction tube 203.

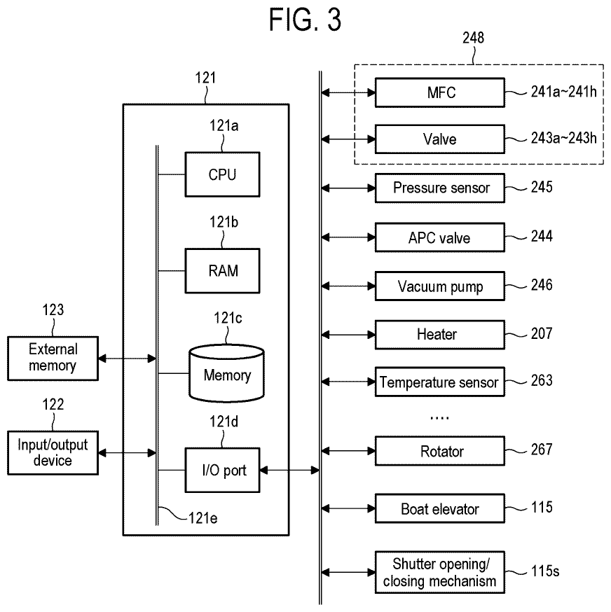

As illustrated in FIG. 3, the controller 121, which is a control part (control means or unit), is configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 including, for example, a touch panel or the like, is connected to the controller 121. Further, the controller 121 is configured to enable a connection to an external memory 123. In addition, the processing apparatus may be configured to include one controller, or a plurality of controllers. In other words, control for performing a processing sequence to be described later may be performed using a single controller, or a plurality of controllers. Further, the plurality of controllers may be configured as a control system in which the controllers are connected to each other through a wired or wireless communication network, and control for performing a processing sequence to be described later may be performed by the entire control system. When the term “controller” is used herein, it may include a single controller, a plurality of controllers, or a control system composed of a plurality of controllers.

The memory 121c includes, for example, a flash memory, a hard disk drive (HDD), and a solid state drive (SSD), or the like. A control program that controls operations of a processing apparatus, a process recipe in which sequences and conditions of substrate processing to be described later are written, etc. are readably stored in the memory 121c. The process recipe functions as a program that combines each sequence of substrate processing to be described later. The program causes, by the controller 121, the substrate processing apparatus to execute each sequence in the recipe on the processing apparatus to obtain an expected result. Hereinafter, the process recipe and the control program may be generally and simply referred to as a “program.” Further, the process recipe may be simply referred to as a “recipe.” When the term “program” is used herein, it may indicate a case of including the recipe, a case of including the control program, or a case of including both the recipe and the control program. The RAM 121b is configured as a memory area (work area) in which programs, data, or others read by the CPU 121a are temporarily stored.

The I/O port 121d is connected to the above-described MFCs 241a to 241h, valves 243a to 243h, pressure sensor 245, APC valve 244, vacuum pump 246, temperature sensor 263, heater 207, rotator 267, boat elevator 115, shutter opening/closing mechanism 115s, and the like.

The CPU 121a is configured to be capable of reading and executing the control program from the memory 121c, as well as reading the recipe from the memory 121c according to an input of an operation command from the input/output device 122, etc. The CPU 121a is configured to be capable of controlling flow rate regulating operations of various substances (various gases) by the MFCs 241a to 241h, the opening/closing operations of the valves 243a to 243h, an opening/closing operation of the APC valve 244, a pressure regulating operation by the APC valve 244 based on the pressure sensor 245, actuating and stopping operations of the vacuum pump 246, a temperature regulating operation by the heater 207 based on the temperature sensor 263, rotation and rotational speed regulating operations of the boat 217 by the rotator 267, an operation of moving the boat 217 up or down by the boat elevator 115, an opening/closing operation of the shutter 219s by the shutter opening/closing mechanism 115s, and so on, according to the contents of the read recipe.

The controller 121 may be configured by installing the above-described program recorded and stored in the external memory 123 on the computer. The external memory 123 includes, for example, a magnetic disk such as a HDD, an optical disk such as a CD, a magneto-optical disk such as a MO, a semiconductor memory such as a USB memory or SSD, and the like. The memory 121c and the external memory 123 are configured as computer-readable recording media. Hereinafter, the memory 121c and the external memory 123 may be generally and simply referred to as a “recording medium.” When the term “recording medium” is used herein, it may indicate a case of including the memory 121c, a case of including the external memory 123, or a case of including both the memory 121c and the external memory 123. In addition, the program may be provided to the computer by using a communication means or unit such as the Internet or a dedicated line, instead of using the external memory 123.

### (2) Processing Process

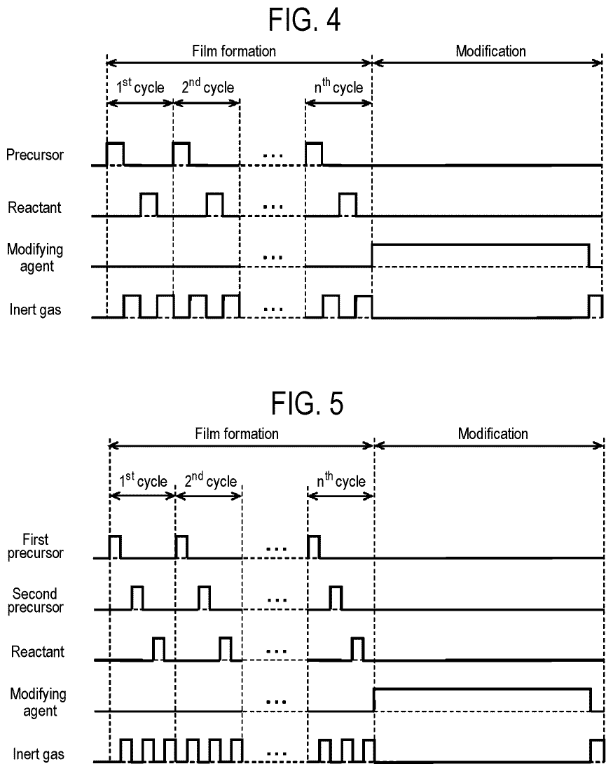

A method of processing a substrate using the above-described processing apparatus, specifically, an example of a processing sequence for forming a film on a surface of the wafer 200 as a substrate, as a process of the manufacturing a semiconductor device, will be described mainly with reference to FIG. 4. In the following descriptions, operations of respective components constituting the processing apparatus are controlled by the controller 121. In addition, the processing apparatus is also referred to as a substrate processing apparatus, a film formation processing apparatus, or a film-forming apparatus. Further, the processing method is also referred to as a substrate processing method, a film formation processing method, or a film-forming method.

The processing sequence in the present embodiment includes:
(a) a step of forming a first film containing at least a portion of a partial structure X and a partial structure Z derived from a partial structure Y on the surface of the wafer 200 by supplying, to the wafer 200, a precursor containing both the partial structure X and the partial structure Y, or a first precursor containing the partial structure X and a second precursor containing the partial structure Y (film formation step); and
(b) a step of modifying the first film formed on the wafer 200 into a second film by exposing the first film to a modifying agent, the second film containing at least a portion of the partial structure X and a smaller amount of the partial structure Z than that contained in the first film (modification step).

In the processing sequence according to the present embodiment, a case in which the above-described first film is formed on the surface of the wafer 200 by supplying the precursor containing both the partial structure X and the partial structure Y in the film formation step will be described. Further, in the processing sequence according to the present embodiment, a case in which a reactant is supplied to the wafer 200 in the film formation step will be described.

In the processing sequence illustrated in FIG. 4, as a representative example, a case in which, in the film formation step, a cycle including a step of supplying the precursor containing both the partial structure X and the partial structure Y to the wafer 200 (precursor supply step) and a step of supplying the reactant to the wafer 200 (reactant supply step) is performed a predetermined number of times (n times, where n is 1 or an integer of 2 or more) will be described.

In the present disclosure, the above-described processing sequence may be denoted as follows. The same notation is used in the following descriptions of modifications and other embodiments.
(Precursor→Reactant)×n→Modifying Agent

The term “wafer” used in the present disclosure may refer to a wafer itself or a stacked body of a wafer and certain layers or films formed on a surface of the wafer. The phrase “surface of the wafer” used in the present disclosure may refer to a surface of a wafer itself or a surface of a certain layer or the like formed on a wafer. The expression “a certain layer is formed on a wafer” used in the present disclosure may refer to “a certain layer is formed directly on a surface of a wafer itself” or “a certain layer is formed directly on a layer formed on a wafer.” The term “substrate” used in the present disclosure may be synonymous with the term “wafer.”

The terms “precursor,” “reactant,” “modifying agent,” and “substance” used in the present disclosure refer to at least one selected from the group of a gaseous substance and a liquid substance. The liquid substance includes a mist-like substance. In other words, each of the precursor, reactant, and modifying agent may include a gaseous substance, a liquid substance such as mist-like substance, or both.

The term “layer” used in the present disclosure refers to at least one selected from the group of a continuous layer and a discontinuous layer. For example, each of the first and second layers may refer to a continuous layer, a discontinuous layer, or a combination of both.

### (Wafer Charging and Boat Loading)

When a plurality of wafers 200 is charged onto the boat 217 (wafer charging), the shutter 219s is moved by the shutter opening/closing mechanism 115s, so that the lower end opening of the manifold 209 is opened (shutter opening). Thereafter, as illustrated in FIG. 1, the boat 217 charged with the plurality of wafers 200 is lifted by the boat elevator 115 and is loaded into the process chamber 201 (boat loading). In this state, the seal cap 219 seals the lower end of the manifold 209 via the O-ring 220b. In this way, the wafers 200 are prepared (provided) inside the process chamber 201.

### (Pressure Regulating and Temperature Regulating)

After the boat loading is completed, an interior of the process chamber 201, that is, a space in which the wafers 200 are placed, is vacuum-exhausted (decompression-exhausted) by the vacuum pump 246 to reach a desired pressure (state of vacuum). At this time, the internal pressure of the process chamber 201 is measured by the pressure sensor 245, and the APC valve 244 is feedback-controlled based on the measured pressure information. Further, the wafers 200 inside the process chamber 201 are heated to reach a desired processing temperature by the heater 207. At this time, a state of supplying electric power to the heater 207 is feedback-controlled based on the temperature information detected by the temperature sensor 263 such that a temperature distribution inside the process chamber 201 becomes a desired temperature distribution. Further, the rotation of the wafers 200 is initiated by the rotator 267. The exhaust of the interior of the process chamber 201 and the heating and rotation of the wafers 200 are continuously performed at least until the processing on the wafers 200 is completed.

### (Film Formation Step)

Thereafter, the subsequent precursor supply step and reactant supply steps are executed in this order.

### [Precursor Supply Step]

In this step, a precursor (precursor gas) is supplied to the wafers 200.

Specifically, the valve 243a is opened to allow the precursor to flow through the gas supply pipe 232a. A flow rate of the precursor is regulated by the MFC 241a, and the precursor is supplied into the process chamber 201 via the nozzle 249a and exhausted from the exhaust port 231a. At this time, the precursor is supplied to the wafers 200 from the lateral side of the wafers 200 (precursor supply). At this time, the valves 243f to 243h are opened to allow an inert gas to be supplied into the process chamber 201 via each of the nozzles 249a to 249c, respectively.

A processing condition when supplying the precursor in the precursor supply step is exemplified as follows:
Processing temperature: room temperature to 700 degrees C., specifically 60 to 600 degrees C.;
Processing pressure: 1 to 2,666 Pa, specifically 10 to 1,333 Pa;
Precursor supply flow rate: 10 to 10,000 sccm, specifically 100 to 5,000 sccm;
Precursor supply time: 1 to 240 seconds, specifically 5 to 120 seconds; and
Inert gas supply flow rate (per gas supply pipe): 0 to 20,000 sccm.

In the present disclosure, notation of a numerical range such as “1 to 2,666 Pa” means that a lower limit value and an upper limit value are included in that range. Thus, for example, “1 to 2,666 Pa” refers to “1 Pa or higher and 2,666 Pa or lower.” The same applies to other numerical ranges. In the present disclosure, the processing temperature means the temperature of the wafers 200 or the internal temperature of the process chamber 201, and the processing pressure means the internal pressure of the process chamber 201. Further, the processing time means the time during which the processing continues. Further, in a case where the supply flow rate includes 0 sccm, “0 sccm” refers to a case in which no substance (gas) is supplied. The same applies to the following descriptions.

As for the precursor, a substance (gas) containing both a partial structure X and a partial structure Y may be used.

The partial structure X includes, for example, at least one selected from the group of Si—CH₂—Si, Si—CH₂—CH₂—Si, Si—R, N(SiR′₃)₃, and CSi₃H. Further, the partial structure Y includes, for example, at least one selected from the group of Si—OR′, Si—NR′—Si, Si—NR′₂, NR′₃, Si—Cl, Si—Br, Si—I, B—Cl, B—Br, B—I, and Si—H.

In addition, Si represents silicon, C represents carbon, H represents hydrogen, N represents nitrogen, O represents oxygen, B represents boron, CI represents chlorine, Br represents bromine, and I represents iodine.

Further, R represents an alkyl group, and R′ independently represents a hydrogen atom or an alkyl group. The alkyl group may be an alkyl group containing 1 to 5 carbon atoms, and specifically an alkyl group containing 1 to 4 carbon atoms. The alkyl group may be either linear or branched. Examples of the alkyl group may include methyl, ethyl, n-propyl, n-butyl, isopropyl, isobutyl, sec-butyl, and tert-butyl groups.

Further, OR′ represents an alkoxy group. The alkoxy group may be an alkoxy group containing 1 to 5 carbon atoms, and specifically an alkoxy group containing 1 to 4 carbon atoms. An alkyl group in the alkoxy group represented by OR′ is the same as the alkyl group described above.

Further, NR′₂ represents an amino group. The amino group may be an amino group containing 1 to 5 carbon atoms, and specifically an amino group containing 1 to 4 carbon atoms.

An alkyl group in the amino group represented by NR′₂ is the same as the alkyl group described above.

In addition, in a case where a structural formula contains a plurality of R′, the plurality of R′ may be the same or different.

For example, Si-containing substances such as a H₃Si—CH₂—CH₂—SiH₂OR′ gas, a N(SiH₃)₂(SiH₂OR′) gas, and a N(SiH₃)₂SiH₂NR′₂ gas may be used as the precursor. One or more of these gases may be used as the precursor.

As for the inert gas, for example, a nitrogen (N₂) gas, or noble gases such as an argon (Ar) gas, a helium (He) gas, a neon (Ne) gas, and a xenon (Xe) gas or the like may be used. One or more of these gases may be used as the inert gas. The same applies to each step to be described later.

By supplying the above-described precursor to the wafer 200 under the above-described processing condition, it is possible to form a first layer on the surface of the wafer 200.

After the first layer is formed on the surface of the wafer 200, the valve 243a is closed to stop the supply of the precursor into the process chamber 201. Then, the interior of the process chamber 201 is vacuum-exhausted to remove residual gaseous substances and the like from the interior of the process chamber 201. At this time, the valves 243f to 243h are opened to supply the inert gas into the process chamber 201 through the nozzles 249a to 249c. The inert gas supplied from the nozzles 249a to 249c acts as a purge gas, thereby purging the interior of the process chamber 201 (purging). The processing temperature during purging may be the same as the processing temperature during the supply of the precursor.

### [Reactant Supply Step]

After the precursor supply step is completed, a reactant (reaction gas) is supplied to the wafer 200, that is, to the wafer 200 on which the first layer is formed on the surface of the wafer 200.

Specifically, the valve 243c is opened to allow the reactant to flow through the gas supply pipe 232c. A flow rate of the reactant is regulated by the MFC 241c, and the reactant is supplied into the process chamber 201 via the nozzle 249c and exhausted from the exhaust port 231a. At this time, the reactant is supplied to the wafer 200 from the lateral side of the wafer 200 (reactant supply). At this time, the valves 243f to 243h may be opened to allow the inert gas to be supplied into the process chamber 201 via each of the nozzles 249a to 249c, respectively.

A processing condition when supplying the reactant in the reactant supply step is exemplified as follows:
Processing pressure: 1 to 13,332 Pa, specifically 10 to 1,333 Pa;
Reactant supply flow rate: 10 to 10,000 sccm, specifically 100 to 2,000 sccm; and
Reactant supply time: 1 to 240 seconds, specifically 5 to 120 seconds. Other processing conditions may be similar to those in supplying the precursor in the precursor supply step.

As for the reactant, for example, an oxygen (O)-containing substance (gas) may be used. For example, an O₂ gas, an O₃ gas, a N₂O gas, a NO₂ gas, a NO gas, a CO₂ gas, and a CO gas may be used as the O-containing substance.

Further, for example, a substance (gas) containing nitrogen (N) and hydrogen (H) may be used as the reactant. Examples of the N- and H-containing substance may include a NH₃ gas, a N₂H₂ gas, a N₂H₄ gas, and a N₃H₈ gas.

One or more of these gases may be used as the reactant.

After the first layer is formed on the wafer 200, by supplying the above-described reactant to the wafer 200 under the above-described processing condition, a reaction between at least a portion of the first layer and the reactant may be caused. Thus, the first layer may be modified (changed) into a second layer.

After the first layer formed on the surface of the wafer 200 is modified into the second layer, the valve 243c is closed to stop the supply of the reactant into the process chamber 201. Then, the residual gaseous substances and the like in the process chamber 201 are removed from the interior of the process chamber 201 under the same processing procedure and processing condition as those in the purging of the precursor supply step (purging). The processing temperature during purging may be the same as the processing temperature during the supply of the reactant.

### [Performing Cycle Predetermined Number of Times]

By performing a cycle, in which the above-described precursor supply step and reactant supply step are performed in this order in a non-simultaneous manner, that is, without synchronization, n times (where n is 1 or an integer of 2 or more), a first film may be formed on the surface of the wafer 200. The above-described cycle may be performed a plurality of times. In other words, a thickness of the second layer formed per cycle may be set to be smaller than a desired film thickness, and the above-described cycle may be performed a plurality of times until the thickness of the first film formed by stacking the second layers reaches the desired film thickness.

In addition, when the above-described Si-containing substance is used as the precursor and the above-described O-containing substance is used as the reactant, a film containing Si and O, that is, a silicon oxide film (SiO film), is formed on the surface of the wafer 200. Further, when the above-described Si-containing substance is used as the precursor and the above-described N- and H-containing substance is used as the reactant, a film containing Si and N, that is, a silicon nitride film (SiN film), is formed on the surface of the wafer 200.

Here, when the above-described substance containing both the partial structures X and Y is used as the precursor, the first film becomes a film containing at least a portion of the partial structure X and a partial structure Z derived from the partial structure Y.

As described above, the partial structure X includes, for example, at least one selected from the group of Si—CH₂—Si, Si—CH₂—CH₂—Si, Si—R, N(SiR′₃)₃, and CSi₃H. For example, when the partial structure X contained in the precursor is Si—CH₂—Si, the first film may contain Si—CH₂—Si itself or a structure in which a specific atom is removed from the partial substructure X, such as Si—CH₂, as the at least a portion of the partial structure X. Further, for example, when the partial structure X contained in the precursor is Si—CH₂—CH₂—Si, the first film may contain Si—CH₂—CH₂—Si itself or a structure in which a specific atom is removed from the partial substructure X, such as Si—CH₂—CH₂ or Si—CH₂, as the at least a portion of the partial structure X.

The partial structure Z is a structure derived from the partial structure Y. The partial structure Z may also refer to a structure generated by a chemical reaction between the precursor containing the partial structure Y and the surface of the wafer 200, or as a structure generated by a thermal decomposition of the precursor containing the partial structure Y. A chemical structure of the partial structure Z may be the same as a chemical structure of the partial structure Y. In other words, the partial structure Z may be obtained by directly introducing the partial structure Y into the first film. Further, the partial structure Z may be generated by altering the partial structure Y. In other words, the partial structure Z may be generated by changing at least one selected from the group of a composition and the chemical structure of the partial structure Y. From these perspectives, the partial structure Y may also refer to an original structure for generating the partial structure Z in the first film.

As described above, the partial structure Y includes, for example, at least one selected from the group of Si—OR′, Si—NR′—Si, Si—NR′₂, NR′₃, Si—Cl, Si—Br, Si—I, B—Cl, B—Br, B—I, and Si—H. The partial structure Z derived from the partial structure Y includes, for example, at least one selected from the group of Si—OR′, Si—NR′—Si, Si—NR′₂, Si—Cl, Si—Br, Si—I, B—Cl, B—Br, B—I, and Si—H. For example, when the partial structure Y contained in the precursor is Si—NR′—Si, the first film may contain Si—NR′—Si itself or a structure in which Si and R′ are substituted, such as Si—NR′₂, as the partial structure Z derived from the partial structure Y. Further, for example, when the partial structure Y contained in the precursor is Si—NR′₂, the first film may contain Si—NR′₂ itself or a structure in which R′ and Si are substituted, such as Si—NR′—Si, as the partial structure Z derived from the partial structure Y.

### (Modification Step)

Thereafter, the following modifying agent exposure step is executed.

### [Modifying Agent Exposure Step]

In this step, the film formed on the surface of the wafer 200, that is, the first film containing the at least a portion of the partial structure X and the partial structure Z derived from the partial structure Y, is exposed to a modifying agent.

Specifically, the valve 243e is opened to allow the modifying agent to flow through the gas supply pipe 232e. A flow rate of the modifying agent is regulated by the MFC 241e, and the modifying agent supplied into the process chamber 201 via the gas supply pipe 232c and the nozzle 249c and exhausted from the exhaust port 231a. At this time, the modifying agent is supplied to the wafer 200 from the lateral side of the wafer 200, and the first film formed on the surface of the wafer 200 is exposed to the modifying agent, so that the first film and the modifying agent react with each other (modifying agent exposure). At this time, the valves 243f to 243h may be opened to allow the inert gas to be supplied into the process chamber 201 via each of the nozzles 249a to 249c.

This step may be performed under a condition in which the reactivity between the partial structure Z contained in the first film and the modifying agent is higher than the reactivity between the at least a portion of the partial structure X contained in the first film and the modifying agent.

Further, this step may be performed under a condition in which the at least a portion of the partial structure X contained in the first film is maintained to be intact.

Further, this step may be performed under a condition in which at least one selected from the group of the composition and the chemical structure of at least a portion of the partial structure Z contained in the first film is changed. In other words, this step may be performed under a condition in which the at least a portion of the partial structure Z contained in the first film is changed into a different partial structure V. Under such a condition, the number of elements constituting the partial structure V may be smaller than the number of elements constituting the partial structure Z. In other words, this step may be performed under a condition in which at least one selected from the group of removing at least one element among elements constituting the partial structure Z contained in the first film, and substituting the at least one element with another element is performed.

In addition, a case of removing at least one element among elements constituting the partial structure Z contained in the first film may include removing a single element, a plurality of elements, or the entirety of elements among the elements constituting the partial structure Z. For example, when the partial structure Z is Si—OR′, this case may include removing Si, removing R′, or removing Si—OR′ itself, among the elements constituting the partial structure Z. Further, for example, when the partial structure Z is Si—NR′—Si, this case may include removing Si, removing R′, or removing Si—NR′—Si itself, among the elements constituting the partial structure Z. Except for removing the partial structure Z itself, these are examples in which the composition and the chemical structure of at least a portion of the partial structure Z is changed. Further, except for removing of the partial structure Z itself, these are examples in which at least a portion of the partial structure Z is changed into a different partial structure V, with the number of elements constituting the partial structure V being smaller than the number of elements constituting the partial structure Z. In the above-described examples, the structure remaining after removing the at least one element among the elements constituting the partial structure Z becomes the partial structure V. By changing the partial structure Z as such, reducing the density of the first film is possible, and making the first film porous to further reduce the density of the first film is also possible.

Further, a case of substituting at least one element among elements constituting the partial structure Z contained in the first film with another element may include substituting a single element, a plurality of elements, or the entirety of elements among the elements constituting the partial structure Z, with another element. For example, when the partial structure Z is Si—OR′, this case may include substituting Si with R′, substituting R′ with Si, or substituting Si—OR′ itself with another element, among the elements constituting the partial structure Z. Further, for example, when the partial structure Z is Si—NR′—Si, this case may include, substituting Si with R′, substituting R′ with Si, or substituting Si—NR′—Si itself with another element, among the elements constituting the partial structure Z. These are examples in which the composition and the chemical structure of at least a portion of the partial structure Z is changed. Further, these are examples in which at least a portion of the partial structure Z is changed into a different partial structure V. In addition, one of these (e.g., the substituting R′ with Si) is an example in which the number of elements constituting the partial structure V is smaller than the number of elements constituting the partial structure Z. In the above-described examples, the structure remaining after substituting the at least one element, among the elements constituting the partial structure Z, with another element becomes the partial structure V. By changing the partial structure Z as such, reducing the density of the first film is possible, and making the first film porous, and thereby further reducing the density of the first film is also possible.

The processing condition during the supply of the modifying agent in the modifying agent exposure step is exemplified as follows:
Processing pressure: 1 to 100,000 Pa, specifically 100 to 100,000 Pa;
Modifying agent supply flow rate: 10 to 10,000 sccm, specifically 100 to 2,000 sccm; and
Modifying agent supply time: 1 to 300 minutes, specifically 10 to 240 minutes. Other processing conditions may be similar to those in supplying the precursor in the precursor supply step.

As for the modifying agent, for example, a substance (gas) containing hydrogen (H) and oxygen (O) may be used. Examples of the H- and O-containing substance may include a H₂O gas, a H₂O₂ gas, H₂ gas+O₂ gas, D₂ gas+O₂ gas, H₂ gas+O₃ gas, and D₂ gas+O₃ gas. Here, D represents deuterium. In addition, the joint mention of two gases such as “H₂ gas+O₂ gas” in the present disclosure refers to a mixed gas of H₂ gas and O₂ gas. In the case of supplying the mixed gas, the two gases may be mixed (pre-mixed) in a supply pipe before being supplied into the process chamber 201. Alternatively, the two gases may be separately supplied into the process chamber 201 from different supply pipes and then be mixed (post-mixed) inside the process chamber 201. One or more of these gases may be used as the modifying agent.

In this step, by exposing the first film formed on the surface of the wafer 200 to the above-described modifying agent under the above-described processing condition, the reaction between the first film and the reactant may be enabled. Thus, it is possible to modify (change) the first film into a second film that contains at least a portion of the partial structure X and a smaller amount of the partial structure Z than that contained in the first film. This enables the change of the first film into a second film of a lower density than that of the first film. Further, in this step, it is possible to make the first film porous, thereby further reducing the density of the first film. In this case, the second film is a porous film. Further, in this step, it may also be possible to change at least a portion of the partial structure Z contained in the first film into a partial structure containing Si—O—Si, that is, a partial structure containing a siloxane, thereby further reducing the density of the first film. In this case, the second film is a film containing siloxane bonds.

After the first film formed on the surface of the wafer 200 is modified into the second film, the valve 243e is closed to stop the supply of the modifying agent into the process chamber 201. Then, the residual gaseous substances and the like in the process chamber 201 are removed from the interior of the process chamber 201 under the same processing procedure and processing condition as those in the purging of the precursor supply step (purging). The processing temperature during purging may be the same as the processing temperature during the modifying agent exposure step.

### (After-Purge and Returning to Atmospheric Pressure)

After the modification step is completed, the inert gas serving as a purge gas is supplied into the process chamber 201 from each of the nozzles 249a to 249c, and is exhausted from the exhaust port 231a. Thus, the interior of the process chamber 201 is purged, and any gases, reaction by-products and the like remaining inside the process chamber 201 are removed from the interior of the process chamber 201 (after-purge). Thereafter, the internal atmosphere of the process chamber 201 is substituted with the inert gas (inert gas substitution), and the internal pressure of the process chamber 201 is returned to the atmospheric pressure (returning to atmospheric pressure).

### (Boat Unloading and Wafer Discharging)

Thereafter, the seal cap 219 is lowered by the boat elevator 115 to open the lower end of the manifold 209. Then, the processed wafer 200 supported by the boat 217 is unloaded (boat unloading) from the lower end of the manifold 209 to the outside of the reaction tube 203. After the boat unloading, the shutter 219s is moved, and the lower end opening of the manifold 209 is sealed by the shutter 219s via the O-ring 220c (shutter closing). The processed wafer 200 is unloaded to the outside of the reaction tube 203, and is discharged from the boat 217 (wafer discharging).

### (3) Effects of Present Embodiment

According to the present embodiment, one or more of the following effects may be achieved.
(a) By performing the above-described film formation step and modification step in this order, it is possible to incorporate at least a portion of the partial structure X into the second film formed on the surface of the wafer, thereby improving an ashing resistance of the second film. Further, it is possible to reduce the amount of the partial structure Z contained in the second film compared to the amount of the partial structure Z contained in the first film, thereby reducing the density of the second film and reducing the k-value (relative dielectric constant) of the second film. In other words, it is possible to achieve low-k characteristics (low dielectric constant) while improving a processing resistance of the second film.
(b) By performing the modification step under the condition in which the reactivity between the partial structure Z contained in the first film and the modifying agent is higher than the reactivity between at least a portion of the partial structure X contained in the first film and the modifying agent, it is possible to effectively reduce the amount of the partial structure Z while maintaining the at least a portion of the partial structure X contained in the first film intact when exposing the first film to the modifying agent. Thus, it is possible to effectively incorporate at least a portion of the partial structure X into the second film while reducing the amount of the partial structure Z contained in the second film compared to the amount of the partial structure Z contained in the first film.
(c) By performing the modification step under the condition in which at least a portion of the partial structure X contained in the first film is maintained to be intact, it is possible to incorporate at least a portion of the partial structure X into the second film, thereby effectively improving the ashing resistance of the second film. In other words, it is possible to effectively improve the processing resistance of the second film.
(d) By performing the modification step under the condition in which at least one selected from the group of the composition and the chemical structure of at least a portion of the partial structure Z contained in the first film is changed, it is possible to effectively reduce the amount of the partial structure Z contained in the second film compared to the amount of the partial structure Z contained in the first film, thereby effectively reducing the density of the second film e and reducing the k-value of the second film. In other words, it is possible to effectively achieve the low-k characteristics of the second film.
(e) By performing the modification step under the condition in which at least a portion of the partial structure Z contained in the first film is changed into a different partial structure V, it is possible to effectively reduce the amount of the partial structure Z contained in the second film compared to the amount of the partial structure Z contained in the first film, thereby effectively reducing the density of the second film and reducing the k-value of the second film. In other words, it is possible to effectively achieve the low-k characteristics of the second film. In addition, by performing the modification step under the above-described conditions, the number of elements constituting the partial structure V may be smaller than the number of elements constituting the partial structure Z. This may more effectively reduce the density of the second film and reduce the k-value of the second film. In other words, it is possible to more effectively achieve the low-k characteristics of the second film.
(f) By performing the modification step under the condition in which at least one selected from the group of removing at least one element, among elements constituting the partial structure Z contained in the first film, and substituting the at least one element with another element is performed, it is possible to effectively reduce the amount of the partial structure Z contained in the second film compared to the amount of the partial structure Z contained in the first film, thereby effectively reducing the density of the second film and reducing the k-value of the second film. In other words, it is possible to effectively achieve the low-k characteristics of the second film.
(g) In the modification step, by changing the first film into the second film of a lower density than that of the first film, it is possible to effectively reduce the k-value of the second film. In other words, it is possible to effectively achieve the low-k characteristics of the second film. Further, by making the first film porous in the modification step, it is possible to more effectively reduce the density of the second film and reduce the k-value of the second film. In other words, it is possible to more effectively achieve the low-k characteristics of the second film.
(h) It is possible to effectively cause the above-described reactions by including at least one selected from the group of Si—CH₂—Si, Si—CH₂—CH₂—Si, Si—R, N(SiR′₃)₃, and CSi₃H as the partial structure X, at least one selected from the group of Si—OR′, Si—NR′—Si, Si—NR′2, NR′₃, Si—Cl, Si—Br, Si—I, B—Cl, B—Br, B—I, and Si—H as the partial structure Y, and at least one selected from the group of Si—OR′, Si—NR′—Si, Si—NR′2, Si—Cl, Si—Br, Si—I, B—Cl, B—Br, B—I, and Si—H as the partial structure Z.
(i) In the modification step, by changing at least a portion of the partial structure Z contained in the first film into a partial structure containing Si—O—Si, that is, a partial structure containing a siloxane, it is possible to more effectively reduce the density of the second film and reduce the k-value of the second film. In other words, it is possible to more effectively achieve the low-k characteristics of the second film.
(j) It is possible to effectively cause the above-described reactions by using a H- and O-containing substance as the modifying agent. Specifically, by using a substance containing at least one H atom and at least one O atom in a single molecule, and more specifically, using a substance containing at least two H atoms and at least one O atom in a single molecule, such as H₂O, it is possible to mildly cause the above-described reactions, that is, the oxidation reaction, and it is also possible to more effectively perform a modification involving a reduction in the density or a porosification of the first film described above.
(k) In the film formation step, by supplying the precursor and the reactant to the wafer, for example, by performing a cycle including the precursor supply step and the reactant supply step a predetermined number of times, it is possible to effectively cause the above-described reactions.
(l) In a case where the chemical structure of the partial structure Z is the same as the chemical structure of the partial structure Y, that is, in a case where the partial structure Z is obtained by directly introducing the partial structure Y into the first film, it is possible to effectively cause the above-described reactions.
(m) In a case where the partial structure Z is generated by altering the partial structure Y, that is, in a case where the partial structure Z is generated by changing at least one selected from the group of the composition and the chemical structure of the partial structure Y, it is possible to effectively cause the above-described reactions.
(n) The above-described effects may also be similarly obtained even in a case in which a predetermined substance is arbitrarily selected and used from among the above-described various precursors, various reactants, various modifying agents, and various inert gases.

### Second Embodiment of Present Disclosure

Subsequently, a second embodiment of the present disclosure will be described mainly with reference to FIG. 5.

The processing sequence according to the present embodiment differs from the above-described first embodiment in that, in the film formation step, both a first precursor containing the partial structure X and a second precursor containing the partial structure Y are supplied. Others are the same as in the first embodiment.

In addition, in the processing sequence of the present embodiment illustrated in FIG. 5 and the following description, as a representative example, a case will be described in which, in the film formation step, a cycle including a step of supplying a first precursor containing the partial structure X to the wafer 200 (first precursor supply step), a step of supplying a second precursor containing the partial structure Y to the wafer 200 (second precursor supply step), and a step of supplying a reactant to the wafer 200 (reactant supply step) is performed a predetermined number of times (n times, where n is 1 or an integer of 2 or more).
(First Precursor→Second Precursor→Reactant)×n→Modifying Agent

In the first precursor supply step, the valve 243d is opened to allow the first precursor to flow through the gas supply pipe 232d. A flow rate of the first precursor is regulated by the MFC 241d and the first precursor is supplied into the process chamber 201 via the gas supply pipe 232a and the nozzle 249a and exhausted from the exhaust port 231a. At this time, the first precursor is supplied to the wafer 200 from the lateral side of the wafer 200 (first precursor supply). At this time, the valves 243f to 243h may be opened to allow the inert gas to be supplied into the process chamber 201 via each of the nozzles 249a to 249c, respectively.

A processing condition when supplying the first precursor in the first precursor supply step is exemplified as follows:
First precursor supply flow rate: 10 to 10,000 sccm, specifically 100 to 2,000 sccm; and
First precursor supply time: 1 to 240 seconds, specifically 5 to 120 seconds. Other processing conditions may be similar to those when supplying the precursor in the precursor supply step of the first embodiment.

As for the first precursor, a substance (gas) containing the partial structure X exemplified in the first embodiment, for example, at least one selected from the group of Si—CH₂—Si, Si—CH₂—CH₂—Si, Si—R, N(SiR′₃)₃, and CSi₃H may be used. For example, a SiH₃CH₂SiH₃ gas, a SiH₃CH₂CH₂SiH₃ gas, a SiH₂(CH₃)₂ gas, or a N(SiH₃)₃ gas may be used as the first precursor. One or more of these gases may be used as the first precursor.

After a predetermined time passes, the valve 243d is closed to stop the supply of the first precursor into the process chamber 201. Then, the residual gaseous substances and the like in the process chamber 201 are removed from the interior of the process chamber 201 under the same processing procedure and processing condition as those in the purging of the precursor supply step of the first embodiment (purging). The processing temperature during purging in this step may be the same as the processing temperature during the supply of the first precursor.

In the second precursor supply step, the valve 243b is opened to allow the second precursor to flow into the gas supply pipe 232b. A flow rate of the second precursor is regulated by the MFC 241b and the second precursor is supplied into the process chamber 201 via the nozzle 249b and exhausted from the exhaust port 231a. At this time, the second precursor is supplied to the wafer 200 from the lateral side of the wafer 200 (second precursor supply). At this time, the valves 243f to 243h may be opened to allow the inert gas to be supplied into the process chamber 201 via each of the nozzles 249a to 249c.

A processing condition when supplying the second precursor in the second precursor supply step is exemplified as follows:
Second precursor supply flow rate: 10 to 10000 sccm, specifically 100 to 2000 sccm; and
Second precursor supply time: 1 to 240 seconds, specifically 5 to 120 seconds. Other processing conditions may be similar to those when supplying the precursor in the precursor supply step of the first embodiment.

As for the second precursor, a substance (gas) containing the partial structure Y exemplified in the first embodiment, for example, at least one structure selected from the group of Si—OR′, Si—NR′—Si, Si—NR′2, NR′₃, Si—Cl, Si—Br, Si—I, B—Cl, B—Br, B—I, and Si—H may be used. For example, a H₃Si—CH₂—CH₂—SiH₂OR′ gas, a (CH₃)₃SiNHSi(CH₃)₃ gas, a N(SiH₃)₂SiH₂NR′₂ gas, a NH₃ gas, or a Si₃Cl₈ gas may be used as the second precursor. One or more of these gases may be used as the second precursor.

After a predetermined time passes, the valve 243b is closed to stop the supply of the second precursor into the process chamber 201. Then, the residual gaseous substances and the like in the process chamber 201 are removed from the interior of the process chamber 201 under the same processing procedure and processing condition as those in the purging of the precursor supply step of the first embodiment (purging). The processing temperature during purging in this step may be the same as the processing temperature during the supply of the second precursor.

The processing procedure and processing condition in the reactant supply step of the second embodiment may be the same as those in the reactant supply step of the first embodiment.

By performing a cycle n times (n is 1 or an integer of 2 or more), the cycle including non-simultaneously, that is, without synchronization, performing the above-described first precursor supply step, second precursor supply step, and reactant supply step, it is possible to form the first film containing at least a portion of the partial structure X and the partial structure Z derived from the partial structure Y on the surface of the wafer 200, as in the film formation step of the first embodiment. The partial structure Z derived from the partial structure Y includes, for example, at least one selected from the group of Si—OR′, Si—NR′—Si, Si—NR′₂, Si—Cl, Si—Br, Si—I, B—Cl, B—Br, B—I, and Si—H, as in the first embodiment.

Thereafter, a modification step is performed to expose the first film formed on the surface of the wafer 200 to a modifying agent, thereby causing a reaction between the first film and the modifying agent. The processing procedure and processing condition in the modification step of the second embodiment may be the same as those in the modification step of the first embodiment.

In the present embodiment as well, it is possible to modify (change) the first film into a second film that contains at least a portion of the partial structure X and a smaller amount of the partial structure Z than that contained in the first film. Then, this enables the change of the first film into the second film of a lower density than that of the first film. Further, in the present embodiment as well, it is possible to make the first film porous, thereby further reducing the density of the first film. In this case, the second film is a porous film. Further, in the present embodiment as well, it may be possible to change at least a portion of the partial structure Z contained in the first film into a partial structure containing Si—O—Si, that is, a partial structure containing a siloxane, thereby further reducing the density of the first film. In this case, the second film is a film containing siloxane bonds. In the present embodiment as well, the same effects as those of the first embodiment are obtained.

### Other Embodiments of Present Disclosure

The embodiments of the present disclosure are described above in detail. However, the present disclosure is not limited to the above-described embodiments, and may be changed in various ways without departing from the gist of the present disclosure. Hereinafter, examples of other embodiments of the present disclosure will be described. In addition, unless otherwise specified, the processing procedure and processing condition in each step of the following other embodiments may be the same as the processing procedure and processing condition in each step of the above-described processing sequence.

For example, substrate processing may be performed using the processing sequence described below (n is 1 or an integer of 2 or more). In these embodiments as well, the same effects as those of the above-described embodiments may be obtained.
(Second Precursor→First Precursor→Reactant)×n→Modifying Agent
(Precursor)×n→Modifying Agent
(First Precursor→Second Precursor)×n→Modifying Agent
(Second Precursor→First Precursor)×n→Modifying Agent

Further, for example, substrate processing may be performed using the processing sequence described below (m and n are respectively 1 or an integer of 2 or more). In these embodiments as well, the same effects as those of the above-described embodiments may be obtained.
[(Precursor→Reactant)×m→Modifying Agent]×n
[(First Precursor→Second Precursor→Reactant)×m→Modifying Agent]×n
[(Second Precursor→First Precursor→Reactant)×m→Modifying Agent]×n
[(Precursor)×m→Modifying Agent]×n
[(First Precursor→Second Precursor)×m→Modifying Agent]×n
[(Second Precursor→First Precursor)×m→Modifying Agent]×n

Further, for example, as in the processing sequence illustrated below, a step of supplying a catalyst to the substrate (catalyst supply step) may be performed at a start timing or the like of each cycle of the film formation step (n is 1 or an integer of 2 or more).
(Catalyst→Precursor→Reactant)×n→Modifying Agent
(Catalyst→First Precursor→Second Precursor→Reactant)×n→Modifying Agent
(Catalyst→Second Precursor→First Precursor→Reactant)×n→Modifying Agent
(Catalyst→Precursor)×n→Modifying Agent
(Catalyst→First Precursor→Second Precursor)×n→Modifying Agent
(Catalyst→Second Precursor→First Precursor)×n→Modifying Agent

Here, the term “catalyst” refers to a substance that remains unchanged before and after a chemical reaction, but changes the reaction rate. A catalyst in a reaction system of the present embodiment exhibits a catalytic effect that changes the reaction rate, but a part of the molecular structure of the catalyst may decompose during the reaction process, changing the catalyst itself before and after the chemical reaction. When the term “catalyst” is used in the present disclosure, it may refer, for convenience, not only to substances that remain unchanged before and after the chemical reaction, but also to substances that may undergo changes before and after the chemical reaction while still exhibiting a catalytic effect that changes the reaction rate.

As for the catalyst, for example, a boron (B)-containing substance (gas) may be used. For example, a BClH₂ gas, a BCl₂H gas, a BCl₃ gas, a BF₃ gas, a BBr₃ gas, or a B₂H₆ gas may be used as the B-containing substance. Here, F represents fluorine.

A processing condition when supplying the catalyst is exemplified as follows:
Catalyst supply flow rate: 10 to 10,000 sccm, specifically 100 to 2,000 sccm; and
Catalyst supply time: 1 to 240 seconds, specifically 5 to 120 seconds. Other processing conditions may be similar to those in supplying the precursor in the precursor supply step of the first embodiment.

In these embodiments as well, the same effects as those of the above-described embodiments may be obtained. Further, according to these embodiments, it is possible to promote the reaction in the above-described film formation step, thereby increasing the thickness of the second layer formed in each cycle.

Further, for example, after performing the film formation step, air may be introduced into the process chamber, and the modifying agent exposure step may be performed in atmospheric atmosphere. Further, for example, after performing the film formation step, the substrate may be unloaded from the process chamber, and the modifying agent exposure step may be performed in atmospheric atmosphere. In these cases, oxygen (O₂) or moisture (H₂O) contained in the air is used as the modifying agent. In these cases as well, the same effects as those of the above-described embodiments may be obtained.

Recipes used for each processing may be prepared individually based on the processing requirements and may be recorded and stored in the memory 121c via an electrical communication line or the external memory 123. Then, when initiating each processing, the CPU 121a may select an appropriate recipe from among the multiple recipes recorded and stored in the memory 121c based on the processing requirements. Consequently, films with various film types, compositions, film qualities, and film thicknesses may be formed with high reproducibility using a processing apparatus. Further, there may be less burden for the operator, and each processing may be initiated rapidly while avoiding operational errors.

The aforementioned recipes may be prepared not only by creating new recipes but also by modifying existing recipes already installed in the processing apparatus, for example. When modifying a recipe, the modified recipe may be installed in the processing apparatus via an electrical communication line or a recording medium on which the recipe is recorded. Further, the existing recipes already installed in the processing apparatus may be directly modified by operating the existing input/output device 122 of the processing apparatus.

In the above-described embodiments, examples in which a film is formed by using a batch-type processing apparatus capable of processing multiple substrates at a time are described. The present disclosure is not limited to the above-described embodiments, and for example, and may be suitably applied to a case in which a film is formed by using a single-wafer-type processing apparatus configured to process a single substrate or several substrates at a time. Further, in the above-described embodiments, examples in which a film is formed by using a processing apparatus including a hot-wall-type process furnace are described. The present disclosure is not limited to the above-described embodiments, and may also be suitably applied to a case in which a film is formed by using a processing apparatus including a cold-wall-type process furnace.

Further, in the above-described embodiments, an example in which the above-described processing sequence is performed in the same process chamber of the same processing apparatus (in-situ) is described. The present disclosure is not limited to the above-described embodiments, and for example, different steps of the above-described processing sequence may be performed respectively in different process chambers of different processing apparatuses (ex-situ).

When using these processing apparatuses as well, it is possible to perform each processing using the same process procedures and processing conditions as those of the above-described embodiments and modifications, and to achieve the same effects as those of the above-described embodiments and modifications.

The above-described embodiments and modifications may be used in appropriate combinations. The processing procedures and processing conditions used in such cases may be the same as the processing procedures and processing conditions in the above-described embodiments and modifications, for example.

According to the present disclosure, it is possible to achieve a technique capable of improving a processing resistance of a film formed on a substrate and achieving a lower dielectric constant.

While certain embodiments are described, these embodiments are presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A processing method comprising:
(a) forming a first film, containing at least a portion of a partial structure X and a partial structure Z derived from a partial structure Y, on a substrate by supplying, to the substrate, a precursor containing both the partial structure X and the partial structure Y, or a first precursor containing the partial structure X and a second precursor containing the partial structure Y; and
(b) modifying the first film formed on the substrate into a second film by exposing the first film to a modifying agent, the second film containing at least a portion of the partial structure X and a smaller amount of the partial structure Z than that contained in the first film.

2. The processing method of claim 1, wherein (b) is performed under a condition in which a reactivity between the partial structure Z contained in the first film and the modifying agent is higher than a reactivity between the at least a portion of the partial structure X contained in the first film and the modifying agent.

3. The processing method of claim 1, wherein (b) is performed under a condition in which the at least a portion of the partial structure X contained in the first film is maintained to be intact.

4. The processing method of claim 1, wherein (b) is performed under a condition in which at least one selected from the group of a composition and a chemical structure of at least a portion of the partial structure Z contained in the first film is changed.

5. The processing method of claim 1, wherein (b) is performed under a condition in which at least a portion of the partial structure Z contained in the first film is changed into a different partial structure V.

6. The processing method of claim 5, wherein a number of elements constituting the partial structure V is smaller than a number of elements constituting the partial structure Z.

7. The processing method of claim 1, wherein (b) is performed under a condition in which at least one selected from the group of removing at least one element, among elements constituting the partial structure Z contained in the first film, and substituting the at least one element with another element is performed.

8. The processing method of claim 1, wherein (b) includes making the first film porous.

9. The processing method of claim 1, wherein (b) includes changing the first film into the second film of a lower density than that of the first film.

10. The processing method of claim 1, wherein the partial structure X includes at least one selected from the group of Si—CH₂—Si, Si—CH₂—CH₂—Si, Si—R, N(SiR′₃)₃, and CSi₃H,
wherein the partial structure Y includes at least one selected from the group of Si—OR′, Si—NR′—Si, Si—NR′₂, NR′₃, Si—Cl, Si—Br, Si—I, B—Cl, B—Br, B—I, and Si—H, and
wherein the partial structure Z includes at least one selected from the group of Si—OR′, Si—NR′—Si, Si—NR′₂, Si—Cl, Si—Br, Si—I, B—Cl, B—Br, B—I, Si—H (where R represents an alkyl group and R′ independently represents a hydrogen atom or an alkyl group).

11. The processing method of claim 10, wherein (b) includes changing at least a portion of the partial structure Z contained in the first film into a partial structure containing Si—O—Si.

12. The processing method of claim 10, wherein (b) includes changing at least a portion of the partial structure Z contained in the first film into a partial structure containing a siloxane.

13. The processing method of claim 1, wherein the modifying agent contains hydrogen and oxygen.

14. The processing method of claim 1, wherein (a) further includes supplying a reactant to the substrate.

15. The processing method of claim 14, wherein (a) includes:
performing a cycle a predetermined number of times, the cycle including supplying the precursor to the substrate and supplying the reactant to the substrate; or
performing a cycle a predetermined number of times, the cycle including supplying the first precursor to the substrate, supplying the second precursor to the substrate, and supplying the reactant to the substrate.

16. The processing method of claim 1, wherein a chemical structure of the partial structure Z is the same as a chemical structure of the partial structure Y.

17. The processing method of claim 16, wherein the partial structure Z is obtained by introducing the partial structure Y into the first film.

18. The processing method of claim 1, wherein the partial structure Z is generated by altering the partial structure Y.

19. The processing method of claim 1, wherein the partial structure Z is generated by changing at least one selected from the group of a composition and a chemical structure of the partial structure Y.

20. A method of manufacturing a semiconductor device comprising the processing method of claim 1.

21. A processing apparatus comprising:
a precursor supply system configured to supply, to a substrate, a precursor containing both a partial structure X and a partial structure Y, or a first precursor containing the partial structure X and a second precursor containing the partial structure Y;
a modifying agent exposure system configured to expose the substrate to a modifying agent; and
a controller configured to be capable of controlling the precursor supply system and the modifying agent exposure system so as to perform a process including:
(a) forming a first film, containing at least a portion of the partial structure X and a partial structure Z derived from the partial structure Y, on the substrate by supplying, to the substrate, the precursor, or the first precursor and the second precursor; and
(b) modifying the first film formed on the substrate into a second film by exposing the first film to the modifying agent, the second film containing at least a portion of the partial structure X and a smaller amount of the partial structure Z than that contained in the first film.

22. A non-transitory computer-readable recording medium storing a program that causes, by a computer, a processing apparatus to perform a process, the process comprising:
(a) forming a first film, containing at least a portion of a partial structure X and a partial structure Z derived from a partial structure Y, on a substrate by supplying, to the substrate, a precursor containing both the partial structure X and the partial structure Y, or a first precursor containing the partial structure X and a second precursor containing the partial structure Y; and
(b) modifying the first film formed on the substrate into a second film by exposing the first film to a modifying agent, the second film containing at least a portion of the partial structure X and a smaller amount of the partial structure Z than that contained in the first film.
